(19) United States
(12) Patent Application Publication
(10) Pub. No.: US 2025/0390333 A1
(43) Pub. Date: Dec. 25, 2025

(54) HARDWARE RESOURCE MAPPING SYSTEM AND METHOD

(71) Applicant: MONTAGE TECHNOLOGY CO., LTD., Shanghai (CN)

(72) Inventors: Kun WEI, Shanghai (CN); Chunhui ZHANG, Shanghai (CN); Yaping LIU, Shanghai (CN); Men LONG, Shanghai (CN)

(73) Assignee: MONTAGE TECHNOLOGY CO., LTD., Shanghai (CN)

(21) Appl. No.: 19/227,527

(22) Filed: Jun. 4, 2025

(30) Foreign Application Priority Data
Jun. 19, 2024 (CN) 2024107977482

(51) Int. Cl. G06F 9/455

(52) U.S. Cl. CPC G06F 9/45558; G06F 2009/4557

(57) ABSTRACT

A hardware resource mapping system and method; the system includes a host with a user space and external devices connected to the host, containing multiple hardware resources divided into M clusters; M is a positive integer; the user space includes n virtual functions and N virtual resources, with a first mapping relationship existing between them, where n and N are positive integers; a second mapping relationship exists between the N virtual resources and the M clusters, ensuring the number of virtual resources mapped to each cluster is greater than or equal to n, and the virtual resources mapped to each cluster correspond to the n virtual functions; for each cluster, a third mapping relationship exists between the virtual resources mapped to the cluster and the hardware resources included in the cluster, ensuring that each virtual resource is mapped to all hardware resources included in the cluster.

### FIELD OF TECHNOLOGY

The present disclosure relates to the field of virtualization, in particular relates to a hardware resource mapping system and method.

### BACKGROUND

As virtualization technology progresses toward fine granularity in the division of physical resources, finer-grained virtualization solutions have emerged under the traditional virtualization technology framework, such as Single Root I/O Virtualization (SR-IOV). SR-IOV is a hardware-based virtualization solution that utilizes the attributes of physical functions (PFs) and virtual functions (VFs) to virtualize a single physical PCIe device into multiple virtual PCIe devices, a VF is created by partitioning a portion of the resources of a PF, and a single PF can create multiple VFs. However, based on these finer-grained virtualization solutions, how to map limited hardware resources more efficiently remains a pressing issue to be addressed.

### SUMMARY

The present disclosure provides a hardware resource mapping system and a method for mapping hardware resources, aiming at efficiently performing hardware mapping. It addresses the issue of routing congestion present in existing technologies while enabling each VF to fully utilize all hardware resources, thereby enhancing system performance.

In some embodiments, the hardware resource mapping system includes a host and an external device connected to the host; the host includes a user space; the external device includes a plurality of hardware resources, the plurality of hardware resources is divided into M clusters, and M is a positive integer. The user space includes n virtual functions and N virtual resources, a first mapping relationship exists between the n virtual functions and the N virtual resources, where n and N are positive integers; a second mapping relationship exists between the N virtual resources and the M clusters, the second mapping relationship is: the quantity of virtual resources mapped to each cluster is greater than or equal to n, and the virtual resources mapped to each cluster correspond to the n virtual functions. For each one of the clusters, a third mapping relationship exists between the virtual resources mapped to the cluster and all hardware resources included in the cluster, the third mapping relationship is: that each virtual resource mapped to the cluster is further mapped to all the hardware resources included in the cluster.

In some embodiments, the first mapping relationship is determined based on n and N.

In some embodiments, the N virtual resources are divided into n groups, the n virtual functions correspond one-to-one to the n groups of the virtual resources, and each virtual function is mapped to the corresponding group of the virtual resources.

In some embodiments, the quantity of virtual resources in each group is greater than or equal to M.

In some embodiments, each cluster includes equal or unequal quantities of the hardware resources.

In some embodiments, the method for mapping hardware resources is applied to a hardware resource mapping system, the hardware resource mapping system includes a host and external devices connected to the host, the host includes a user space, the user space includes n virtual functions and N virtual resources, the external device includes a plurality of hardware resources, and the plurality of the hardware resources is divided into M clusters, and n, N and M are all positive integers. The method for mapping hardware resources includes: determining the first mapping relationship between the n virtual functions and the N virtual resources; determining the second mapping relationship between the N virtual resources and the M clusters, the second mapping relationship is: a quantity of virtual resources mapped to each cluster is greater than or equal to n, the virtual resources mapped to each cluster correspond to the n virtual functions; for each one of the clusters, determining a third mapping relationship between the virtual resources mapped to the cluster and all hardware resources included in the cluster, wherein the third mapping relationship is: each virtual resource mapped to the cluster is further mapped to all the hardware resources included in the cluster.

The present disclosure achieves an interwoven mapping between hardware resources, VFs, and virtual resources through three groups of mapping relationships. This approach not only resolves routing congestion issues at the physical implementation level that are present in traditional mapping schemes but also ensures that each VF can access all hardware resources. This approach improves the utilization of hardware resources and, consequently, enhances the system performance of the hardware resource mapping system.

### BRIEF DESCRIPTION OF THE DRAWINGS

FIG. 1 shows a schematic diagram of a hardware resource mapping system according to one embodiment of the present disclosure.

FIG. 2 shows a schematic diagram of a third mapping relationship between the virtual resources mapped to Cluster 0 and the hardware resources included in Cluster 0 according to one embodiment of the present disclosure.

FIG. 3 shows a flowchart of a method for mapping hardware resources according to one embodiment of the present disclosure.

### DETAILED DESCRIPTION

The embodiments of the present disclosure will be described below. Those skilled can easily understand disclosure advantages and effects of the present disclosure according to contents disclosed by the specification. The present disclosure can also be implemented or applied through other different specific embodiments. Various details in this specification can also be modified or changed based on different viewpoints and disclosures without departing from the spirit of the present disclosure. It should be noted that the following embodiments and the features of the following embodiments can be combined with each other if no conflict will result.

It should be noted that the drawings provided in this disclosure only illustrate the basic concept of the present disclosure in a schematic way, so the drawings only show the components closely related to the present disclosure. The drawings are not necessarily drawn according to the quantity, shape, and size of the components in actual implementation; during the actual implementation, the type, quantity, and proportion of each component can be changed as needed, and the layout of the components can also be more complicated.

In addition, the terms like “first” and “second” are used for descriptive purposes only, and are not to be construed as indicating or implying relative importance or implicitly specifying quantities of technical features indicated. Thus, features qualified with terms like “first” and “second” may explicitly or implicitly include at least one such feature. Additionally, the technical solutions between various embodiments can be combined, but this must be based on the premise that such combinations can be implemented by those skilled in the art. If the combination of technical solutions results in contradictions or cannot be implemented, it should be considered that such combinations do not exist and are not within the scope of the present disclosure.

Current virtualization technology solutions, such as SR-IOV and Scalable I/O Virtualization, can divide a single physical device into multiple virtual devices or virtual ports, thus providing each virtual machine (VM) with a separate access channel so that multiple virtual machines can access the physical device at the same time. Taking SR-IOV as an example, SR-IOV-enabled devices can have one or more PFs (physical functions), PFs act as resource management entities for the device and can be managed by the PF driver in the host operating system. Under each PF, multiple VFs (virtual functions) can be created and share the physical resources of the PF, and each VF can be assigned to a VM for access; each VF can manage a portion of the hardware resources of the device, and the portion of hardware resources managed by each VF are mapped to the user space and presented as virtual resources in the user space, for the VF to manage.

However, existing mapping schemes are challenged by issues such as cabling blockages at a physical implementation level, constraints on the quantity of virtual resources, and defects where VFs fail to fully leverage hardware resources. As a result, the efficient mapping of limited hardware resources remains a critical problem that requires urgent attention.

To solve the above-mentioned problems, one embodiment of the present disclosure provides a system for mapping hardware resources; the system for mapping hardware resources may include a host and an external device connected to the host, and a virtualization layer, such as a hypervisor or a virtual machine monitor, may be installed in the host to create, operate, and manage virtual machines. The host may be any suitable type of computer, computing device, or server, and the external device may be a PCIe device.

The technical solutions in embodiments of the present disclosure will be described in detail below in conjunction with accompanying drawings of the present disclosure.

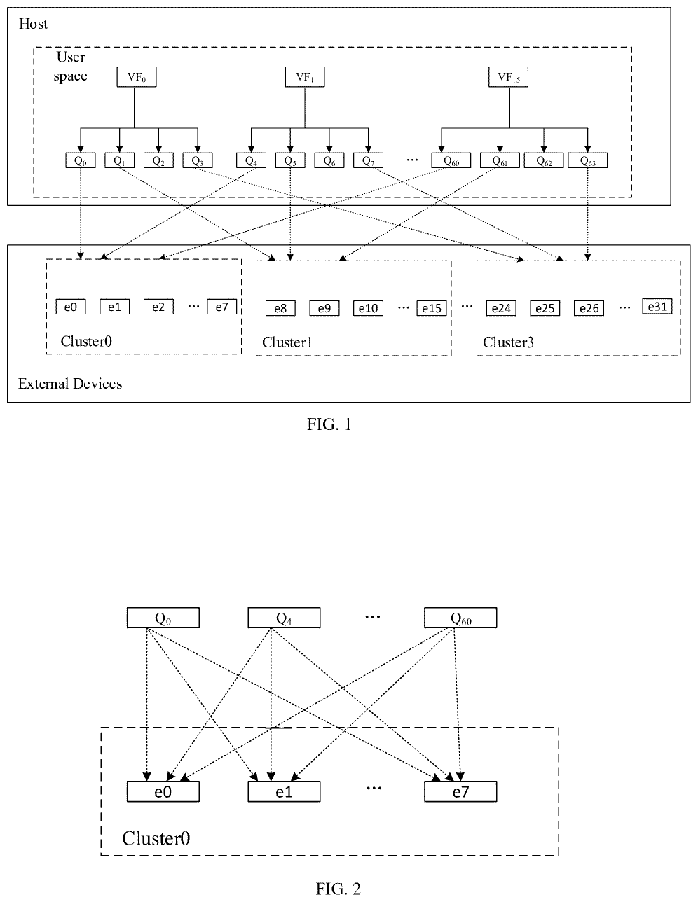

FIG. 1 shows a schematic diagram of a hardware resource mapping system according to one embodiment of the present disclosure. A user space of a host may include n VFs with N virtual resources Q, and both n and N are positive integers. The n VFs are {VF₀, VF₁, VF₂, . . . , VF₍ₙ₋₁₎} and the N virtual resources Q are {Q₀, Q₁, Q₂, . . . , Q_{(N-1)}}. A mapping relationship between the n VFs and the N virtual resources Q (hereinafter also referred to as a first mapping relationship) can be determined based on the quantity of VFs and the quantity of virtual resources Q.

In one embodiment, the N virtual resources are divided into n groups, the n virtual functions correspond one-to-one to the n groups of the virtual resources, and each VF is mapped to a corresponding group of the virtual resources.

In one embodiment, in the n groups of virtual resources Q, a quantity of virtual resources Q included in each group may be equal. For example, each group may include q virtual resources Q, where q is a positive integer and N=n*q. Each VF corresponds to q virtual resources Q. In this case, the first mapping relationship is as follows: each VF can be mapped to q virtual resources Q. FIG. 1 is illustrated with n=16 and N=64, in which case, q=4, i.e., each VF may manage 4 virtual resources Q correspondingly. As shown in FIG. 1, VF₀ corresponds to virtual resources Q₀, Q₁, Q₂, Q₃, VF₁ corresponds to virtual resources Q₄, Q₅, Q₆, Q₇, . . . , and VF₁₅ corresponds to virtual resources Q₆₀, Q₆₁, Q₆₂, Q₆₃.

In one embodiment, in the n groups of virtual resources Q, the quantity of virtual resources Q included in each group may be unequal, i.e., different VFs may correspond to different quantities of virtual resources Q.

The external device may include various hardware resources. The specific type of hardware resources depends on the type of external device. For example, when the external device is a storage device, the hardware resources may include a storage space of the storage device, when the external device is a computational acceleration device, the hardware resources may include an acceleration engine of the computational acceleration device (e.g., an encryption/decryption computational acceleration device); the external device may include any suitable hardware resources.

In one embodiment, a plurality of hardware resources of the external device is divided into M clusters, and M is a positive integer; each cluster may include an equal or an unequal quantity of hardware resources.

In one embodiment, in the n groups of virtual resources Q, each group includes a quantity of virtual resources Q that is greater than or equal to M, i.e., the quantity of virtual resources Q mapped to each VF is not less than M. For example, each VF corresponds to q virtual resources Q, when q is greater than or equal to M. FIG. 1 is illustrated with q equal to M. For another example, each VF corresponds to a different quantity of virtual resources Q, in which case, the quantity of virtual resources Q mapped to each VF is greater than or equal to M.

Referring to FIG. 1, the external device in FIG. 1 is a computational acceleration device, and the hardware resources of the external device are acceleration engines, where the hardware resources are divided into four clusters, i.e., Clusters 0 to 3, and each cluster includes eight acceleration engines, for example, Cluster 0 includes acceleration engines e0, e1, e2, . . . , e7.

A mapping relationship between the N virtual resources Q and the M clusters (hereinafter also referred to as a second mapping relationship) may be determined based on the first mapping relationship described above. In one embodiment, the second mapping relationship between the N virtual resources Q corresponding to the n VFs and the M clusters is as follows: the quantity of virtual resources Q that are mapped to each cluster is greater than or equal to n, and the virtual resources Q that are mapped to each cluster correspond to the n VFs; that is, corresponding to each cluster, at least one virtual resource Q in the group of virtual resources Q corresponding to each VF is mapped to the cluster, to ensure that all clusters are accessible to each VF.

As an example, with Clusterₘ corresponding to N virtual resources Q and each VF corresponding to q virtual resources Q, the N virtual resources Q mapped to Clusterₘ can be represented as.

$${Cluster}_{m} = \{ {Q}_{m} , {Q}_{m + q} , {Q}_{m + 2 q} , {Q}_{m + 3 q} ... {Q}_{m + ( n - 1 ) q} \} , m = 0 , 1 , …… , \qquad ( M - 1 )$$

Qₘ corresponds to VF₀ and is mapped to Clusterₘ, Q_{m+q} corresponds to VF₁ and is mapped to Clusterₘ, and Q_{m+2q} corresponds to VF₂ . . . , so that it is ensured that all clusters are accessible to each VF.

As another example, different VFs correspond to different quantities of virtual resources Q; supposing there are three VFs: VF₀, VF₁, VF₂, these VFs correspond to a total of seven virtual resources Q: Q₀, Q₁, . . . , Q₆, where VF₀ may correspond to the virtual resources Q₀, Q₁, VF₁ may correspond to the virtual resources Q₂, Q₃, and VF₂ may correspond to the virtual resources Q₄, Q₅, Q₆. The quantity of clusters is two, i.e., Cluster 0, Cluster 1. The virtual resources mapped to Cluster 0 are, for example, Q₀, Q₂, and Q₄; the virtual resources mapped to Cluster 1 are, for example, Q₁, Q₃, and Q₅; and the remaining virtual resource Q₆, may be optionally mapped to either Cluster 0 or Cluster 1, for example, if Q₆ is mapped to Cluster 0, then the virtual resources corresponding to Cluster 0 (Q₀, Q₂, Q₄, Q₆) correspond to three VFs, and the virtual resources corresponding to Cluster 1 (Q₁, Q₃, Q₅) also correspond to three VFs, so each VF can access all clusters.

Further, corresponding to any Clusterₘ, a mapping relationship (also referred to hereinafter as a third mapping relationship) between the virtual resources Q that are mapped to Clusterₘ and the hardware resources included in Clusterₘ is as follows: each of the virtual resources Q that are mapped to Clusterₘ is mapped to all of the hardware resources included in Clusterₘ; that is, each virtual resource Q that is mapped to Clusterₘ corresponds to all hardware resources included in Clusterₘ.

FIG. 2 shows a schematic diagram of a third mapping relationship between the virtual resources mapped to Cluster 0 and the hardware resources included in Cluster 0 according to one embodiment of the present disclosure. As shown in FIG. 2, the virtual resources that are mapped to Cluster 0 are Q₀, Q₄, . . . , Q₆₀, these virtual resources correspond to VF₀, VF₁, . . . , VF₁₅ respectively, and each of these virtual resources is mapped to eight hardware resources e0, e1, . . . , e7 in Cluster 0. This mapping allows each VF to access all hardware resources, ensuring the full utilization of hardware resources.

In some embodiments, the present disclosure also provides a method for mapping hardware resources, the method for mapping hardware resources is applied to the hardware resource mapping system.

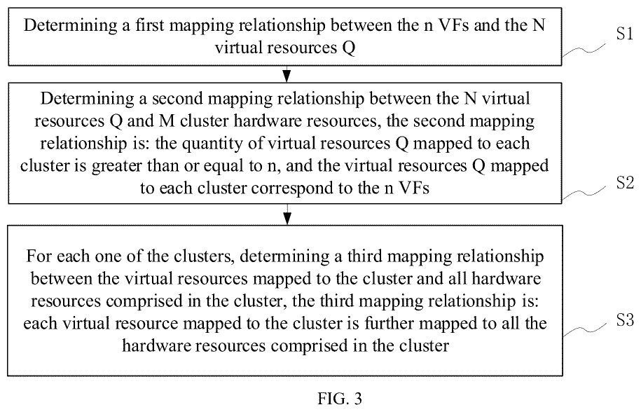

As shown in FIG. 3, the method of mapping hardware resources provided by one embodiment of the present disclosure includes:

S1, determining the first mapping relationship between the n VFs and the N virtual resources Q.

In some embodiments, the N virtual resources Q are divided into n groups, the n VFs correspond one-to-one with the n groups of virtual resources Q; each VF is mapped to a corresponding group of virtual resources Q (the first mapping relationship), and the n and N are positive integers; corresponding to the n groups of virtual resources Q, the quantity of virtual resources Q included in each group may be equal or unequal.

S2, determining the second mapping relationship between the N virtual resources Q and M cluster hardware resources, wherein the second mapping relationship is: the quantity of virtual resources Q mapped to each cluster is greater than or equal to n, and the virtual resources Q mapped to each cluster correspond to the n VFs.

As described above, the hardware resources of the external device are divided into M clusters, M is a positive integer, and different clusters may include equal or unequal quantities of hardware resources. To ensure that each VF has access to all clusters, in any of the clusters, at least one virtual resource Q of the group of virtual resources Q corresponding to each VF may be mapped to the cluster. The quantity of virtual resources Q included in the group of virtual resources Q corresponding to each VF is not less than M.

S3, for each one of the clusters, determining the third mapping relationship between the virtual resources mapped to the cluster and all hardware resources included in the cluster, wherein the third mapping relationship is: each virtual resource mapped to the cluster is further mapped to all the hardware resources included in the cluster.

That is, each of the virtual resources Q corresponding to any cluster corresponds to all the hardware resources included in that cluster. Since the virtual resources Q corresponding to each cluster correspond to n VFs, each VF of those n VFs can access all hardware resources in all clusters.

The embodiments of the present disclosure divide hardware resources into clusters and make each cluster correspond to a plurality of virtual resources, and the plurality of virtual resources corresponds to different virtual functions, this mapping relationship between the clusters and the virtual resources makes all the clusters accessible to each virtual function. Further, each cluster is fully connected, i.e., each of the plurality of virtual resources corresponding to each cluster corresponds to all of the hardware resources included in that cluster, thereby allowing each virtual function to access all of the hardware resources in all of the clusters, allowing the hardware resources to be fully utilized.

The scope of the hardware mapping method disclosed in the embodiments of this application is not limited to the sequence of operations listed. Any scheme realized by adding or subtracting operations or replacing operations of the traditional techniques according to the principle of this application is included within the scope of disclosure of this application.

In the several examples provided in the present disclosure, it should be understood that the systems, devices, or methods disclosed, may be realized in other ways. For example, the above-described embodiments of the device are only schematic, e.g., the division of modules/units is only a logical functional division, can be divided differently when realized, e.g., a plurality of modules or units can be combined or can be integrated into another system, or some features can be ignored, or not implemented. On another point, the mutual coupling, direct coupling or communication connection shown or discussed may be an indirect coupling or communication connection through some interface, device module, or unit, which may be electrical, mechanical, or otherwise.

The modules/units illustrated as separated components may or may not be physically separated, and the components shown as modules/units may or may not be physical modules, i.e., they may be located in a single place or they may also be distributed to a plurality of network units. Some or all of these modules/units can be selected to fulfill the purpose of the embodiments of the present disclosure according to actual needs. For example, the various functional modules/units in various embodiments of the present application may be integrated with a single processing module, or the individual modules/units may physically exist separately, or two or more modules/units may be integrated with a single module/unit.

Those skilled in the art should further realize that the units and algorithmic steps of the various examples described in conjunction with the embodiments disclosed herein are capable of being implemented in electronic hardware, computer software, or a combination of both and that the composition and steps of the various examples have been described in the foregoing description in general terms according to function to clearly illustrate the interchangeability of the hardware and software. Whether these functions are performed in hardware or software depends on the specific application and design constraints of the technical solution. Those skilled may use different methods for each particular application to implement the described functionality, but such implementations should not be considered outside the scope of the present disclosure.

The descriptions of the processes or structures corresponding to each of the above accompanying drawings have their emphasis, and the parts that are not described in detail in a certain process or structure can be referred to as the relevant descriptions of other processes or structures.

The above-mentioned embodiments are merely illustrative of the principle and effects of the present application instead of restricting the scope of the present application. Modifications or variations of the above-described embodiments may be made by those skilled in the art without departing from the spirit and scope of the present application. Therefore, all equivalent modifications or changes made by those who have common knowledge in the art without departing from the spirit and technical concept disclosed by the present application shall be still covered by the claims of the present disclosure.

What is claimed is:

1. A hardware resource mapping system, comprising: a host and external devices connected to the host; wherein the host comprises a user space; wherein the external devices comprise a plurality of hardware resources, the plurality of hardware resources is divided into M clusters, and M is a positive integer;
wherein the user space comprises n virtual functions and N virtual resources, a first mapping relationship exists between the n virtual functions and the N virtual resources, wherein n and N are positive integers;
wherein a second mapping relationship exists between the N virtual resources and the M clusters, the second mapping relationship is: a quantity of virtual resources mapped to each cluster is greater than or equal to n, and the virtual resources mapped to each cluster correspond to the n virtual functions; and
wherein for each one of the M clusters, a third mapping relationship exists between the virtual resources mapped to the cluster and hardware resources comprised in the cluster, and the third mapping relationship is: each virtual resource mapped to the cluster is further mapped to all hardware resources comprised in the cluster.

2. The hardware resource mapping system according to claim 1, wherein the first mapping relationship is determined based on n and N.

3. The hardware resource mapping system according to claim 1, wherein the N virtual resources are divided into n groups, the n virtual functions correspond one-to-one to the n groups of the virtual resources, and each virtual function is mapped to a corresponding group of the virtual resources.

4. The hardware resource mapping system according to claim 3, wherein a quantity of virtual resources comprised in each group is greater than or equal to M.

5. The hardware resource mapping system according to claim 1, wherein the M clusters comprise equal or unequal quantities of hardware resources.

6. A method for mapping hardware resources, wherein the method for mapping hardware resources is applied to a hardware resource mapping system, the hardware resource mapping system comprises a host and an external device connected to the host, wherein the host comprises a user space, the user space comprises n virtual functions and N virtual resources, the external device comprises a plurality of hardware resources, and the plurality of the hardware resources is divided into M clusters, and wherein n, N and M are all positive integers, the method for mapping hardware resources comprises:
determining a first mapping relationship between the n virtual functions and the N virtual resources;
determining a second mapping relationship between the N virtual resources and the M clusters, wherein the second mapping relationship is: a quantity of virtual resources mapped to each cluster is greater than or equal to n, the virtual resources mapped to each cluster correspond to the n virtual functions; and
for each one of the clusters, determining a third mapping relationship between the virtual resources mapped to the cluster and all hardware resources comprised in the cluster, and the third mapping relationship is: each virtual resource mapped to the cluster is further mapped to all the hardware resources comprised in the cluster.

7. The method for mapping hardware resources according to claim 6, wherein the first mapping relationship is determined based on n and N.

8. The method for mapping hardware resources according to claim 6, wherein the N virtual resources are divided into n groups, the n virtual functions correspond one-to-one to the n groups of the virtual resources, and each virtual function is mapped to the corresponding group of the virtual resources.

9. The method for mapping hardware resources according to claim 8, wherein a quantity of virtual resources in each group is greater than or equal to M.

10. The method for mapping hardware resources according to claim 6, wherein the M clusters comprise equal or unequal quantities of hardware resources.
